(19) United States
(12) Patent Application Publication
(10) Pub. No.: US 2025/0011228 A1
(43) Pub. Date: Jan. 9, 2025

(54) METHOD FOR PRODUCING A STRUCTURE FOR MICRO-ELECTROMECHANICAL SYSTEMS

(71) Applicant: LPKF LASER & ELECTRONICS SE, Garbsen (DE)

(72) Inventors: Roman OSTHOLT, Langenhagen (DE); Norbert AMBROSIUS, Garbsen (DE); Maik BERTKE, Haste (DE)

(21) Appl. No.: 18/712,280

(22) PCT Filed: Oct. 25, 2022
(86) PCT No.: PCT/EP2022/079749

§ 371 Date: May 22, 2024

(30) Foreign Application Priority Data
Nov. 26, 2021 (DE) 10 2021 131 084.9

(51) Int. Cl. C03C 21/00

(52) U.S. Cl. CPC C03C 21/002

(57) ABSTRACT

A method for producing a structure for a micro-electromechanical system (MEMS) includes deforming a projecting or overhanging formation of the structure within or out of a main plane of extent, such that the formation consequently assumes, in a rest position, a shape which is bent, curved, and/or angled with an upper side forming a convex outer side and an underside forming a concave outer side. The shape is obtained by a structuring having been introduced into at least one of the outer sides and/or by partial coverings having been applied to the at least one of the outer sides, and the structure then having been subjected to a treatment by which compressive stresses and/or tensile stresses in uncovered regions are introduced into layers close to a surface such that a desired deformation is generated by virtue of a difference in the stresses at the different outer sides.

### CROSS REFERENCE TO RELATED APPLICATIONS

This application is a U.S. National Phase application under 35 U.S.C. § 371 of International Application No. PCT/EP2022/079749, filed on Oct. 25, 2022, and claims benefit to German Patent Application No. DE 10 2021 131 084.9, filed on Nov. 26, 2021. The International Application was published in German on Jun. 1, 2023 as WO 2023/094094 A1 under PCT Article 21(2).

### FIELD

The invention relates to a method specified for producing a structure, in particular made from glass, for micro-electromechanical systems (MEMS), in particular an MEMS actuator configured as an electrostatic micro-actuator. Furthermore, the invention relates to a micro-electromechanical system produced according to the method.

### BACKGROUND

The term MEMS has come to cover micro-electromechanical systems, in particular therefore components with dimensions in the order of magnitude of a few millimeters to several millimeters, which combine electrical and mechanical components, wherein the inner structural sizes vary within the range of a few nanometers to hundreds of micrometers.

It is of vital importance in the production of such microsystems to monitor and adjust mechanical stresses of the structures for the quality, stability, and functionality of the corresponding circuits or systems.

In most applications, it is desirable if the structures and the layers on the substrate are as free as possible of mechanical stresses. Excessively high mechanical stresses in the structures can cause various problems such as, for example, poor adhesion of individual layers on the materials underneath.

Depositing coatings on the structure usually creates, whatever the method of application, mechanical stresses in the layers close to the surface as tensile stresses and compressive stresses. In principle, a layer with tensile stress causes a concave deformation of the structure, and a layer with compressive stress causes a convex deformation.

It is also known to use the stresses within the layers to assist specific properties. For example, experiments are known in which mechanical stresses in the membranes are adjusted by capacitive pressure sensors such that the membranes follow a bent profile at atmospheric pressure.

In addition to the mechanical stresses which occur as thermal stresses because of different coefficients of thermal expansion of the substrate, the stresses which are caused by changes in morphology within the layer are referred to as intrinsic stresses.

In order to improve the durability of glass, in particular for use in displays, ion exchange methods for producing a hardened surface are known. Here, potassium ions penetrate the glass surface of the molten glass and replace the smaller sodium ions originally contained in the glass. When the glass cools, compressions occur by virtue of the larger potassium ions such that a layer in compressive stress is generated which forms the durable surface.

In a method for producing a glass object according to DE 10 2017 008 610 A1, the chemical hardening of glass serves to avoid a deformation.

US 2020/095 163 Al discloses a method for producing an object from thin glass for use in electronic appliances and as an optical appliance, in which the method comprises ion exchange treatment. Non-uniform ion exchange treatment is achieved here by the complete or partial masking of regions of the outer surface. A curvature can thus be induced in the thin glass because of the surface compressive stress which results from the non-uniform ion exchange treatment such that the thin glass can assume a bent shape and be fixed in this configuration.

### SUMMARY

In an embodiment, the present disclosure provides a method for producing a structure for a micro-electromechanical system (MEMS). The method includes deforming a projecting or overhanging formation of the structure, at least in some places, within or out of a main plane of extent, such that the formation consequently assumes, in a rest position of the structure, a shape which is bent, curved, and/or angled, at least in some places, with an upper side forming a convex outer side and with an underside of the formation forming a concave outer side. The shape is obtained by a structuring having been introduced, at least in some places, into at least one of the outer sides and/or by partial coverings having been applied to the at least one of the outer sides, and the structure then having been subjected to a treatment by which compressive stresses and/or tensile stresses in uncovered regions are introduced into layers close to a surface such that a desired deformation is generated in the deforming of the formation by virtue of a difference in the compressive stresses and/or tensile stresses at the different outer sides of the formation.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a formation of a structure with longitudinal cuts in the direction of the main extent;

FIG. 2 shows the formation with cuts transverse to the direction of the main extent;

FIG. 3 shows the formation with a plurality of coverings spaced apart from one another in the direction of the main extent;

FIG. 4 shows the deformed formation after an ion exchange in a use as an electrostatic microactuator; and

FIG. 5 shows a further deformed formation in a use as a thermal switch.

### DETAILED DESCRIPTION

In an embodiment, the invention provides a method for producing a microstructure from glass, by means of which compressive stresses within the structure can be better monitored or controlled.

In another embodiment, the invention provides an MEMS actuator produced according to this method and which meets the in particular highest demands on the mechanical properties including the dimensional accuracy and at the same time high design flexibility in the shaping.

According to an embodiment of the invention, a method is thus provided for producing a structure, for example made from glass, in which a formation of the structure, which is in particular projecting or overhanging and is in particular flexible or movable during use of the structure, is deformed at least in some places permanently or irreversibly within a plane forming, for example, a main plane of extent or out of this plane and consequently assumes, in the rest position of the structure in which it is unstressed by the external action of force, a shape which is deflected at least in some places within the plane and/or out of the plane, in particular is bent, curved, and/or angled, as a basic shape with an upper side forming a convex outer side and with an underside of the formation forming a concave outer side, by a structuring being introduced at least in some places at least into an outer surface, partial coverings being applied, and/or a structuring being introduced and partial coverings for manipulation, in particular passivation or delaying of a treatment comprising, for example, an ion exchange, being applied to the outer side, and compressive stress and/or tensile stresses then being introduced into the structure into the layers close to the surface as a consequence of the treatment in the uncovered regions and/or unstructured or differently structured regions such that the desired deformation is generated without the additional external action of force by virtue of a difference in the amount and/or direction of the stresses on the upper side of the formation compared with the underside.

In contrast to the prior art, in which the stresses within the structure are used to harden the structure and moreover simultaneously also counteract a deformation, embodiments of the invention make use of the surprising insight that, by modifying the structure in a targeted way by structurings or coverings, the compressive stresses or tensile stresses which consequently act non-uniformly or asymmetrically in the opposite outer sides, a targeted deformation can be achieved, in particular also by adjusting the local degree of deformation, in order thus to generate very generally plastically deformed, non-plane structures. These deformed structures can, after deformation, be elastically deformed as part of the original material properties, for example a formation as a functional support can thus be deflected, such that the structures thus generated are optimally suited for MEMS actuators.

In other words, an embodiment of the invention relates to the production of such a functional element, in particular to the introduction of a corresponding pretensioning for generating a bent basic shape.

An example of application is the contacting of surfaces, for example of metal switch contacts. To do this, a partial or complete structuring is introduced into the initially plane, strip-like substrate on one side or both sides, which structuring results in a surface enlargement or, by virtue of a covering, i.e. a layer for passivation with respect to the subsequent treatment, for example an ion exchange, a reduction in the surface of a first outer side compared with the opposite second outer side.

According to an embodiment of the invention, the treatment which preferably comprises an ion exchange is used for the purpose of the deformation, in particular therefore for introducing a curvature, angling, or bending out of the plane of the originally plane substrate. 3D contours can consequently be generated in a targeted fashion in the glass or corresponding structures, wherein the further properties remain virtually unchanged.

For understanding embodiments of the invention, reference is made to the insight that the introduced compressive or tensile stresses depend not only just on the area of the surface enlarged by the structuring but also on its direction. This effect is known per se to a person skilled in the art from the field of the hardening of glass in displays. Expressed in a simplified fashion, the structurings only have an effect when they run in the direction of the main extent of the structure to be deformed, in particular the formation, for the effective enlargement of the surface regions. In the case of groove-shaped longitudinal cuts, in addition to the remaining surface, the area in the groove base and additionally also the wall area which is likewise oriented in the direction of the main extent are thus created. The compressive or tensile stresses are accordingly increased by longitudinal cuts. Conversely, cuts in the transverse direction cause an opposite effect because the wall areas are oriented in a transverse direction to the main extent. In addition, the action of the compressive or tensile stresses in the region of the outer surface of the substrate is reduced by the cuts running in a transverse direction such that, because of the treatment, the compressive stresses are lower on the outer side treated in this way than in the untreated outer side.

Assuming an outer side with the above described groove-shaped structurings and an opposite untreated outer side, the treatment accordingly results, in the case of the structuring in the longitudinal direction of the main extent of the structure or formation to be deformed, in a convex deformation and, in the case of the structuring in the transverse direction to the main extent, in a concave deformation.

It can be easily understood that a wide range of structuring options result according to this principle which cannot be listed definitively and are suited to implementing even complex 3D deformations of a reproducible quality, wherein the structurings can be produced according to individual patterns.

Such a structuring can be achieved mechanically or, for example, by means of electromagnetic radiation, in particular by a laser.

A reduction of a surface which can be used, for example, for the ion exchange effects a corresponding decrease in the compressive stresses or tensile stresses such that in this way in principle the same effect is achieved but without the need to partially remove material from the surface. Instead, the surface remains fundamentally unchanged.

The covering which is to be understood as, for example, a layer for the passivation or delaying of the treatment can be applied permanently to the surface or be removed again after the treatment has been performed, which has an advantageous effect especially in such applications in which the surface finish is to remain as unchanged as possible, for example in the case of use as a mirror. Such a covering can, for example, be printed onto the surface of the structure or applied as a film.

The covering can also consist of a complex, regular, or irregular pattern. Alternatively, a complete covering can also be applied which has differing degrees of permeability in different regions for the ion exchange and thus delays the latter to a greater or lesser extent.

A combination of different structurings and/or coverings can of course also be implemented in order thus to further improve the efficiency of the deformation. In addition, the surface inside the structured regions can also have a surface which promotes the treatment, for example by ion exchange, for example a microstructuring or a defined roughness.

Although the structuring is introduced fundamentally on the outer surface of the outer side, it is not excluded according to an embodiment of the invention that a modification of a lower-lying layer spaced apart from the outer surface is performed by virtue of the structuring with no change to the surface in order thus to promote or delay, for example, the migration of the ions within the structure.

The further task of creating a structure, produced according to this method, for micro-electromechanical systems (MEMS), which meets in particular the highest demands on the mechanical properties with a simultaneously high design flexibility in the shaping, is achieved according to an embodiment of the invention by a structure, for example made from glass, which has a formation which is non-plane at least in some places and is concavely and/or convexly curved. According to an embodiment of the invention, a targeted deformation of the glass structure is thus enabled for the first time by introducing local or partial surface stresses, in particular in relation to an opposite, preferably parallel outer side. It should be emphasized that this type of deformation does not require a negative mold such that in this way individual products can also be produced in an economically viable manner. In addition, the desired deformations can also be introduced in those regions of the glass structure which are largely inaccessible inside the microactuator such that new structural possibilities are opened up for the production of micro-electromechanical systems.

A particularly promising embodiment of the invention is also achieved by the convex side of the deformation enclosing, with an element, in particular a glass element, which is plane at least in some places, a gap with a non-linear opening angle such that the structure thus created is optimally suited to the production of an electrostatic microactuator. The convexly curved surface here serves as a curved or arched electrode, for example in conjunction with a flexible glass spring, which is provided with an electrically conductive coating at its facing surfaces.

The gap with a non-linear opening angle is here not bounded by two straight lines and instead at least one boundary line follows at least partially a curve, wherein discontinuities are also not excluded. The opening angle is consequently not constant and the gap width increases in a non-linear fashion. Furthermore, the change in the opening angle, which can be described mathematically as a first derivative of the curve function, can follow a linear or non-linear progression. The gap width can thus change in a non-linear fashion, wherein the opening angle is not constant.

Another, likewise particularly advantageous embodiment of the invention is also achieved by it being possible for the formation to bear against a contact surface in a deformed position counter to its elastic restoring force. Because of external actions, for example the actions of force or a change in temperature, elastic deflection of the formation takes place, as a result of which the bearing contact with the contact surface is interrupted; for example, as a result of a supply of thermal energy a deformation occurs because of the metallic coating with a thermal coefficient of expansion which is different from the glass material, such that the structure can be used as a thermal switch.

The invention allows different embodiments. For further illustration of its basic principle, one of these is illustrated in the drawings and described below.

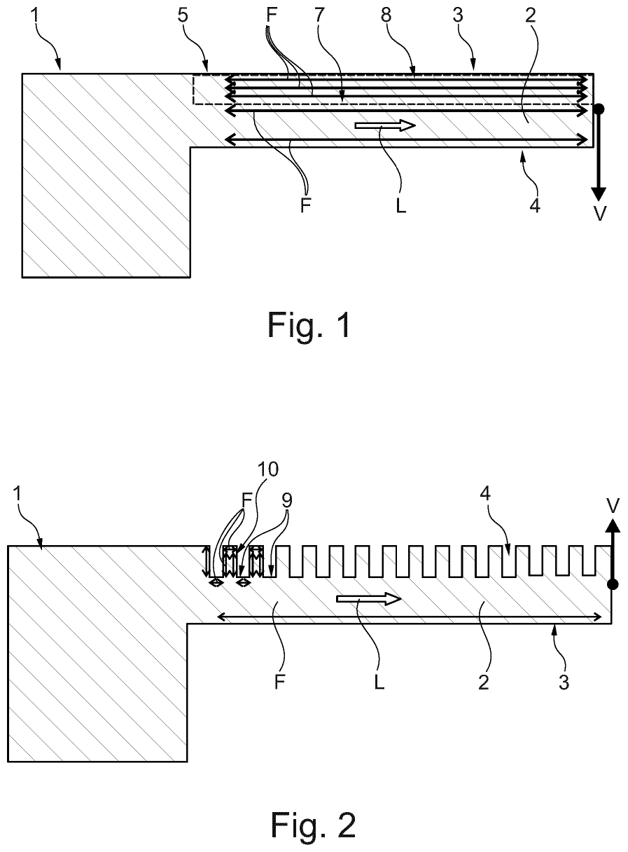

The production of microstructured mechanical structures 1 consisting of a glass substrate for the production of micro-electromechanical systems is described in detail below on the basis of FIGS. 1 to 5.

The structure 1 has a freely overhanging formation 2 which is used in different applications as a movable element, for example as a lever, and for this purpose retains its elastic property even after the irreversible deformation.

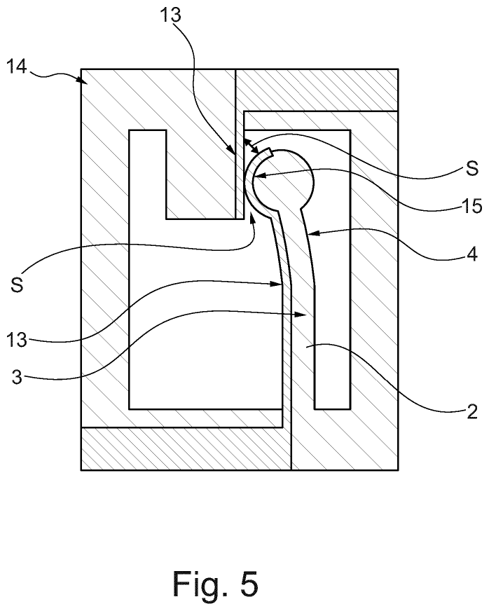

In order to achieve an irreversible deformation of the formation 2, ion exchange takes place at the two opposite outer sides 3, 4 according to the principle of chemical hardening, with an upper side forming the convex outer side 3 and an underside of the formation forming the concave outer side 4, which can be seen in the exemplary embodiments of FIGS. 4 and 5.

The embodiment of the invention here makes use of the fact that, by virtue of a suitable prior treatment before performing the ion exchange method, the ion exchange takes place at the upper side and the underside in a non-uniform fashion, in particular to a lesser extent or just in a delayed fashion on one outer side 4, such that the compressive stresses F introduced as a result differ from one another on the different sides of the formation 2.

The purpose of the prior treatment according to an embodiment of the invention is to accelerate or to delay the ion exchange by a structuring 5 and/or by a partial covering 6 of the surface at least on one outer side 3, 4 such that, after the treatment and the acting non-uniform compressive stresses F have ended, the deformation V occurs automatically and in a manner which is adjustable according to the type and extent of the structuring 5 and the covering 6.

Possible structurings 5 and the covering 6 are explained below purely by way of example on the basis of three variants, wherein countless further possibilities for changing the surface are moreover conceivable and implementable in practice.

A variant is shown in FIG. 1 in which the structuring 5 is introduced into the upper side of the formation 2 by a groove-shaped depression 7 parallel to the main direction of extent L, whereas the surface on the underside is not changed. The wall area 8 bounding the groove-shaped depression 7, by virtue of its orientation parallel to the main direction of extent L, and the compressive stresses F which act as a result within the wall area 8 likewise parallel to the main direction of extent L, actively contribute, as a result of the ion exchange according to the principle of vector addition, to the compressive stresses F which act overall. The deformation V of the formation 2 which acts after the ion exchange is indicated by a direction arrow such that the convex outer side 3 of the formation 2 is adjusted, as can be seen in FIG. 4.

In contrast, groove-shaped depressions 9 with an orientation transverse to the main direction of extent L result in the bounding wall areas 10 having no additional effect on the desired deformation. What is more, the action of the compressive stresses F in those regions of the original surface which are interrupted by the depressions 9 is significantly weakened and causes at most a deformation V of the wall areas 10 between the depressions 9 but not a deformation V of the total formation 2 in the main direction of extent L. As a result of the ion exchange taking place simultaneously over the whole area of the underside and the compressive stresses F thus introduced, a deformation V of the formation 2 occurs, the direction of which is again illustrated by a direction arrow, such that a concave outer side 4 results on the upper side of the formation 2.

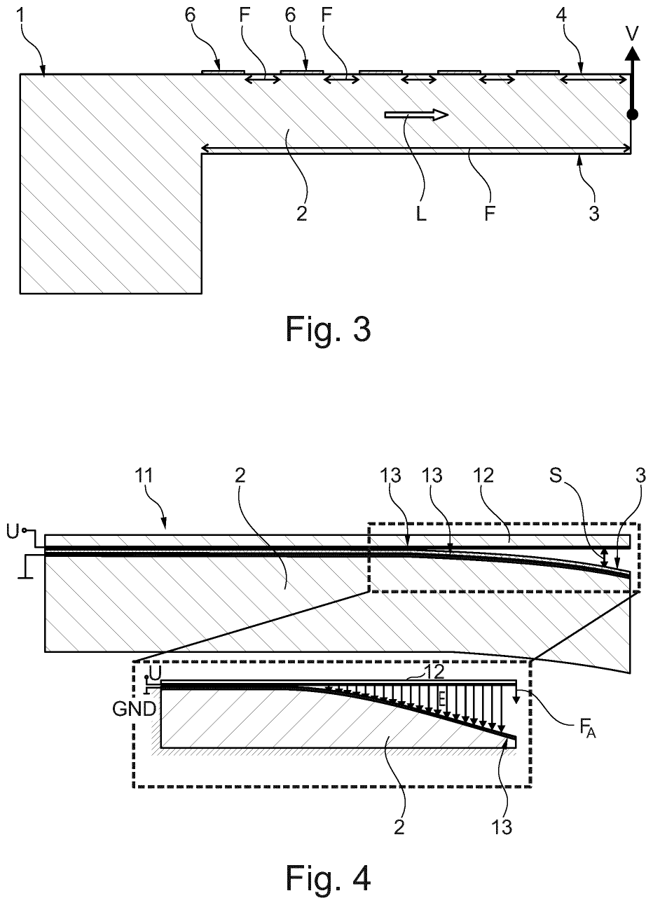

A comparable reduction of the compressive stresses F introduced into the upper side is also caused by a partial covering 6 shown in FIG. 3 by masking of the surface. In particular, an ion exchange does not occur, or occurs only to a limited extent, in the covered regions such that in sum the compressive stresses F on the upper side are reduced and a concave outer side 4 of the upper side of the formation 2 results, corresponding to the direction arrow (deformation V). By virtue of the differing spacings between the coverings 6, the radius of curvature of the deformation V in the main direction of extent L can be adjusted to be different in some places.

Different possible applications of structures 1 curved in this way are illustrated in FIGS. 4 and 5. In the case of an electrostatic microactuator 11 according to FIG. 4, the convex outer side 3 of the formation 2 encloses, with a flexible glass element 12 which is plane in some places, a gap S with a non-linear opening angle. The convexly curved outer side 3 here serves as a curved or arched electrode in conjunction with the glass element 12 serving as a flexible glass spring. The outer side 3 and the opposite area of the glass element 12 are provided with an electrically conductive coating 13 on their facing surfaces. An electrical field E and an actuator force F_{A} perpendicularly to the surface of the glass element 12 are created, as illustrated, by the application of a voltage U.

An MEMS structure 14 configured as a thermal switch or a thermal sensor is illustrated in a top view in FIG. 5, wherein the deformed formation 2 bears against a contact surface 15. A change in the temperature causes an elastic deflection of the formation 2, as a result of which the bearing contact with the contact surface 15 and hence the electrical contacting of the metallic coatings 13 are interrupted, wherein the gap S with its non-linear opening angle is created between the contact surface 15 and the metallic coatings 13.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE SIGNS

1 structure
2 formation
3 outer side
4 outer side
5 structuring
6 covering
7 depression
8 wall area
9 depression
10 wall area
11 microactuator
12 glass element
13 coating
14 MEMS structure
15 contact surface
F compressive stress
L main direction of extent
V deformation
S gap
E electrical field
U voltage
FA actuator force

1. A method for producing a structure for a micro-electromechanical system (MEMS), the method comprising:
deforming a projecting or overhanging formation of the structure, at least in some places, within or out of a main plane of extent, such that the formation consequently assumes, in a rest position of the structure, a shape which is bent, curved, and/or angled, at least in some places, with an upper side of the formation forming a convex outer side and with an underside of the formation forming a concave outer side, the shape being obtained by a structuring having been introduced, at least in some places, into at least one of the outer sides and/or by partial coverings having been applied to the at least one of the outer sides, and the structure then having been subjected to a treatment by which compressive stresses and/or tensile stresses in uncovered regions are introduced into layers close to a surface such that a desired deformation is generated in the deforming of the formation by virtue of a difference in the compressive stresses and/or tensile stresses at the different outer sides of the formation.

2. The method as claimed in claim 1, wherein the structuring is introduced into the at least one of the outer sides with an orientation at least substantially parallel to the main direction of extent of the formation.

3. The method as claimed in claim 1, wherein a plurality of parallel groove-shaped depressions are introduced into the at least one of the outer sides for the structuring.

4. The method as claimed in claim 1, wherein the structuring is introduced into the at least one of the outer sides transversely to the main direction of extent of the formation.

5. The method as claimed in claim 1, wherein a degree of curvature of the formation is adjusted by a spacing of the coverings and/or an orientation of the structuring.

6. The method as claimed in claim 1, wherein the treatment comprises an ion exchange method.

7. A structure for a micro-electromechanical system (MEMS), produced by the method as claimed in claim 1, wherein the structure has a formation which is bent at least in some places in one direction.

8. The structure as claimed in claim 7, wherein the convex outer side of the formation encloses with at least one glass element, which is planar at least in some places, a gap with a non-linear opening angle.

9. The structure as claimed in claim 7, wherein the structure is made at least substantially of glass.

10. The structure as claimed in claim 7, wherein at least one of the outer sides of the formation is provided with an electrically conductive coating, at least in some places.

11. The structure as claimed in claim 7, wherein the formation is configured to bear against a contact surface in a deformed position counter to an elastic restoring force of the formation.

12. The structure as claimed in claim 7, wherein the structure is a microactuator.

13. The method as claimed in claim 7, wherein the structure is a microactuator.
